(19) United States
(12) Patent Application Publication
(10) Pub. No.: US 2002/0163060 A1
(43) Pub. Date: Nov. 7, 2002

(54) Component of gallium arsenide and fabrication method

(76) Inventor: Peter Grambow, Munchen (DE)

Correspondence Address: LERNER AND GREENBERG, P.A., PATENT ATTORNEYS AND ATTORNEY AT LAW, Post Office Box 2480, Hollywood, FL, 33022-2480, US

(21) Appl. No.: 10/138,653

(22) Filed: May 3, 2002

(30) Foreign Application Priority Data
May 3, 2001 (DE) 101 21 549.5

(51) Int. Cl. H01L 21/28; H01L 29/20; H01L 31/0304; H01L 29/40

(52) U.S. Cl. 257/615; 438/933; 257/745; 438/604

(57) ABSTRACT

A GaAs substrate is reduced to a thickness of no more than 30 μm, preferably no more than 10 μm, by grinding. The substrate thus has the characteristics of a film, which prevents breakage of the substrate. A metallization can be provided on the rear of the substrate. The thermal characteristics are improved, because the heat can be transferred to the rear side of the substrate more effectively. Because of the smaller dimensions and good heat dissipation, smaller housings can be utilized. Extremely small holes (micro via holes) are etched into the substrate and provided with via hole fillers.

### BACKGROUND OF THE INVENTION

Field of the Invention

The invention lies in the semiconductor technology field and relates, more specifically, to semiconductor components in a gallium arsenide material system.

Semiconductor components such as transistors, MMICs (Modularly Mounted Integrated Circuits), HBTs (Heterobipolar Transistors) or HEMTs (High Electron Mobility Transistors) in a GaAs material system have long been known. The disadvantage of that semiconductor material is that, as a mixed crystal, it is extremely brittle and breaks easily. Accordingly, substrates and finished components require careful handling. Despite corresponding measures, in the fabrication of GaAs components, the yield of functional components is substantially reduced as a result of breakage.

### SUMMARY OF THE INVENTION

It is accordingly an object of the invention to provide a component on GaAs and a production method, which overcome the above-mentioned disadvantages of the heretofore-known devices and methods of this general type and which suggests an alternative with which semiconductor components can be fabricated in a GaAs material system with a higher yield of functional specimens.

With the foregoing and other objects in view there is provided, in accordance with the invention, a semiconductor configuration, comprising:

a GaAs substrate having a thickness of at most 30 μm; and

a component on the substrate.

In accordance with an added feature of the invention, the substrate has a thickness of no more than 10 μm.

In accordance with an additional feature of the invention, the substrate has holes formed therein with a diameter of at most 1 μm and penetrating through the substrate.

In accordance with another feature of the invention, the holes are filled with conductive material forming via hole filler.

With the above and other objects in view there is also provided, in accordance with the invention, a method of fabricating a component, which comprises:

providing a GaAs substrate having a main side and a rear side opposite the main side;

forming at least one electrically conductively doped region in the main side of the substrate; and/or epitaxially growing at least one layer of semiconductor material on the main side of the substrate; and

subsequently thinning the substrate from the rear side to a thickness of at most 30 μm, and preferably at most 10 μm.

In accordance with a concomitant feature of the invention, holes are etched into the thinned substrate, the holes forming plated through-holes.

In other words, the objects of the invention are achieved with the inventive component for which a GaAs substrate is provided that has a thickness d of at most approximately 10 μm to approximately 30 μm. In this thickness, the material exhibits the characteristics of a film, specifically flexibility and elasticity, which prevent breakage of the substrate. In certain embodiments, an applied (i.e. vapor- or sputter-deposited) metallization can be provided in order to improve the tensile strength of the substrate and to reduce the flexibility within desired limits, particularly so that integrated semiconductor components on the substrate are not subjected to excessive mechanical tensions.

The structure of a component which is provided with such a substrate can be substantially improved over conventional semiconductor components, it being possible to etch extremely small holes for plated through-holes (via holes) in the form of what are known as micro via holes into a substrate of the given thickness. The diameter of a micro via hole can equal 1 μm or smaller. Vertical contacting through the substrate by means of electrically conductive via hole fillers which are inserted into these holes is therefore unproblematic even in these very small dimensions. Furthermore, improved thermal characteristics of the components emerge, because the heat which emerges during operation can be more effectively removed to the side of the substrate that is averted from the integrated component through a thin substrate. The smaller dimensions compared to semiconductor components of the prior art and the good heat removal make it possible to utilize smaller housings.

Other features which are considered as characteristic for the invention are set forth in the appended claims.

Although the invention is illustrated and described herein as embodied in a component on GaAs and fabrication method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawing.

### BRIEF DESCRIPTION OF THE DRAWING

FIG. 1 is a perspective view of a substrate with an epitaxial layer on top;

FIG. 2 is a partly broken-away, perspective view of a sequence of layers, with a top layer having a contact surface; and

FIG. 3 is a top perspective view of a further exemplary embodiment of the invention.

### DESCRIPTION OF THE PREFERRED EMBODIMENTS

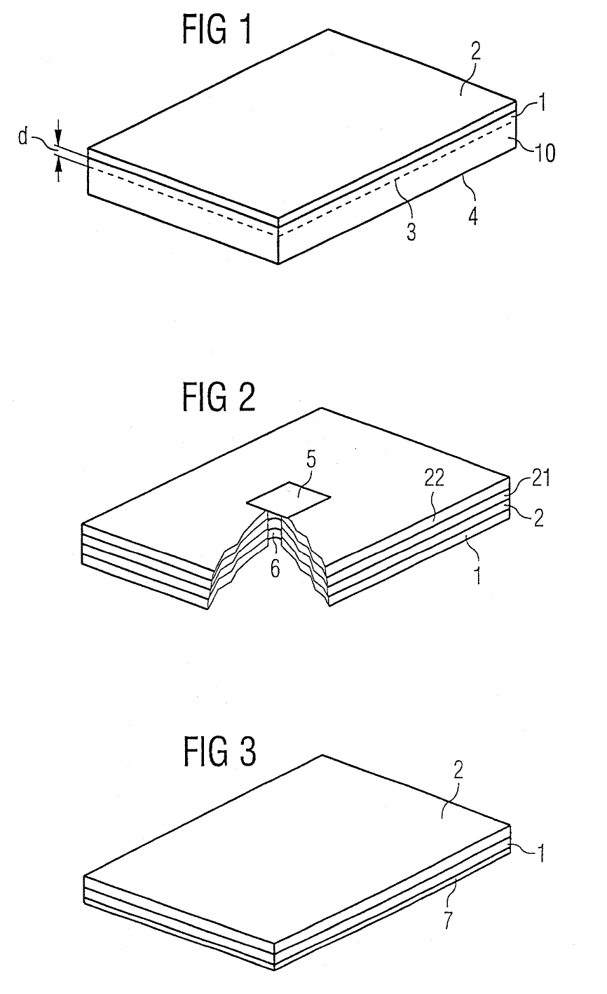

Referring now to the figures of the drawing in detail and first, particularly, to FIG. 1 thereof, there is shown a GaAs substrate 10 in its original thickness, on which only one epitaxially grown layer 2 is exemplarily provided. A plurality of layers can be present, which are structured differently depending on the function of the component, and which can be provided with electrically conductively doped regions and contacts and wired up into circuits by way of structured metallization planes. The details correspond to known components and are not represented here. The substrate has a rear side 4. The substrate 1 of the component according to the invention is thinned down to a rear region 3 (represented by dotted lines), i.e. to a thickness d of approximately 30 μm (preferably to 10 μm).

FIG. 2 represents another exemplary embodiment of the invention. Here, several grown layers 2,21,22 are provided, the topmost of which is provided with a contact surface 5. The contact region 5 consists of an electrically conductive material, preferably a metal, and it is located over a via hole 6 (illustrated at the vertex of the section in the layer structure) in conductive contact with the conductive via hole filler which has been inserted into the via hole 6. Tungsten can serve as the material of the via hole filler (this being utilized elsewhere for this purpose), whereby the diameter of the via hole 6 and thus the diameter of the plated through-hole formed with the via hole filler is substantially smaller than in conventional unthinned components, preferably being 1 μm at most.

FIG. 3 represents a further exemplary embodiment of the invention. Here, the rear side of the thinned substrate 1 which is provided with a grown layer 2 has a vapor-deposited or sputter-deposited metallization 7.

The inventive component is advantageously fabricated in that, starting from a main side of the substrate, at least one conductively doped region is formed in the material of a GaAs substrate and/or at least one layer of semiconductor material is epitaxially grown on the substrate, and the thickness of the substrate is then reduced to a thickness below the given values in that the substrate is worn thin from the opposite main side. The terms wearing thin or thinning encompass chemical-mechanical polishing (CMP) or lapping.

I claim:

1. A semiconductor configuration, comprising:
a GaAs substrate having a thickness of at most 30 μm; and
a component on said substrate.

2. The semiconductor configuration according to claim 1, wherein said substrate has a thickness of no more than 10 μm.

3. The semiconductor configuration according to claim 1, wherein said substrate has holes formed therein with a diameter of at most 1 μm and penetrating through said substrate.

4. The semiconductor configuration according to claim 3, which comprises conductive material forming via hole filler filling said holes.

5. A method of fabricating a component, which comprises:
providing a GaAs substrate having a main side and a rear side opposite said main side;
performing at least one step selected from the group consisting of:
forming at least one electrically conductively doped region in the main side of the substrate; and
epitaxially growing at least one layer of semiconductor material on the main side of the substrate; and
subsequently thinning the substrate from the rear side to a thickness of at most 30 μm.

6. The method according to claim 5, which comprises etching holes into the thinned substrate, the holes forming plated through-holes.
